(19) United States
(12) Patent Application Publication
(10) Pub. No.: US 2026/0107752 A1
(43) Pub. Date: Apr. 16, 2026

(54) SEMICONDUCTOR PACKAGE AND METHOD OF MANUFACTURING THE SEMICONDUCTOR PACKAGE

(71) Applicant: Samsung Electronics Co., Ltd., Suwon-si (KR)

(72) Inventor: Sunjae KIM, Suwon-si (KR)

(73) Assignee: Samsung Electronics Co., Ltd., Suwon-si (KR)

(21) Appl. No.: 19/243,891

(22) Filed: Jun. 20, 2025

(30) Foreign Application Priority Data
Oct. 10, 2024 (KR) 10-2024-0137775

(51) Int. Cl. H01L 23/48; H01L 23/00; H01L 23/31; H01L 23/538; H01L 25/065

(52) U.S. Cl. CPC H10W 20/20; H10W 70/611; H10W 70/685; H10W 74/141; H10W 90/00; H10W 74/15; H10W 90/722; H10W 90/732

(57) ABSTRACT

A semiconductor package may include a lower semiconductor chip; an upper semiconductor chip on the lower semiconductor chip, the upper semiconductor chip including a substrate having a first surface facing the lower semiconductor chip and a second surface opposing the first surface, and a measurement via pattern portion in a peripheral region of the substrate; and a sealing member covering the upper semiconductor chip on the lower semiconductor chip and exposing the second surface of the substrate. The measurement via pattern portion may include first dummy via structures extending from the first surface of the substrate to the second surface such that end portions thereof are exposed from the second surface of the substrate; and second dummy via structures extending from the first surface of the substrate to a depth such that end portions thereof are not exposed from the second surface of the substrate.

### PRIORITY STATEMENT

This application claims priority under 35 U.S.C. § 119 to Korean Patent Application No. 10-2024-0137775, filed on Oct. 10, 2024 in the Korean Intellectual Property Office (KIPO), the contents of which are herein incorporated by reference in their entirety.

### BACKGROUND

### 1. Field

Example embodiments relate to a semiconductor package and/or a method of manufacturing the semiconductor package. More particularly, example embodiments relate to a multi-chip package including a plurality of different stacked chips and/or a method of manufacturing the same.

### 2. Description of the Related Art

In manufacturing a system in package (SIP) including stacked chips, an upper semiconductor chip may be stacked on a lower semiconductor chip or an interposer under high temperature and high pressure by a solder reflow process or a thermo-compression bonding process, and a molding member may be formed to cover the upper semiconductor chip. At this time, operating costs of measuring equipment for measuring alignment accuracy of the upper semiconductor chip may be high, and the measurement accuracy of the thickness of the upper semiconductor chip may be reduced during a grinding process for removing an upper surface of the molding member. In addition, warpage may occur due to differences in thermal expansion coefficient and structural differences between wirings and insulating layers of the upper semiconductor chip.

### SUMMARY

Some example embodiments provide a semiconductor package capable of performing optical measurement at low cost during manufacturing of the semiconductor package and/or improving bonding characteristics of stacked semiconductor chips.

Some example embodiments provide a method of manufacturing the semiconductor package.

According to an example embodiment, a semiconductor package may include a lower semiconductor chip; an upper semiconductor chip on the lower semiconductor chip, the upper semiconductor chip including a substrate having a first surface facing the lower semiconductor chip and a second surface opposing the first surface, a front insulating layer on the first surface of the substrate, and a measurement via pattern portion in a peripheral region of the substrate; and a sealing member covering the upper semiconductor chip on the lower semiconductor chip and exposing the second surface of the substrate. The measurement via pattern portion may include first dummy via structures and second dummy via structures. The first dummy via structures may extend in a thickness direction from the first surface of the substrate to the second surface such that end portions of the first dummy via structures may be exposed from the second surface of the substrate. The second dummy via structures may extend in the thickness direction from the first surface of the substrate to a depth in the substrate such that end portions of the second dummy via structures may not be exposed from the second surface of the substrate.

According to an example embodiment, a semiconductor package may include an interposer; a semiconductor chip on the interposer, the semiconductor chip including a substrate having a first surface facing the interposer and a second surface opposing the first surface, a front insulating layer on the first surface of the substrate, and a measurement via pattern portion in a peripheral region of the substrate; and a sealing member covering the semiconductor chip. The sealing member may be on the interposer and may expose the second surface of the substrate. The measurement via pattern portion may include corner measurement pattern portions respectively provided at four corner portions of the substrate. Each of the corner measurement pattern portions may include first dummy via structures and a second dummy via structures. The first dummy via structures may extend in a thickness direction from the first surface of the substrate to the second surface such that end portions of the first dummy via structures may be exposed from the second surface of the substrate. The second dummy via structures may extend in the thickness direction from the first surface of the substrate to a depth in the substrate such that end portions of the second dummy via structures may not be exposed from the second surface of the substrate.

According to an example embodiment, a semiconductor package may include a first semiconductor chip; a second semiconductor chip on the first semiconductor chip, the second semiconductor chip having a central region and a peripheral region surrounding the central region, the second semiconductor chip including a measurement via pattern portion in the peripheral region; and a sealing member covering the second semiconductor chip, the sealing member being on the first semiconductor chip and exposing an upper surface of the second semiconductor chip. The measurement via pattern portion may include corner measurement pattern portions respectively provided at four corner portions of the second semiconductor chip and side measurement pattern portions respectively provided at four side portions of the second semiconductor chip. Each of the corner measurement pattern portions and the side measurement pattern portions may include first dummy via structures and second dummy via structures. The first dummy via structures may extend into at least a portion of the second semiconductor chip in a thickness direction such that end portions of the first dummy via structures are exposed from the upper surface of the second semiconductor chip. The second dummy via structures may extend partially through the second semiconductor chip in the thickness direction such that end portions of the second dummy via structures are not exposed from the upper surface of the second semiconductor chip.

According to an example embodiment, a semiconductor package may include a first semiconductor chip, a second semiconductor chip that is stacked on the first semiconductor chip via conductive bumps and has a measurement via pattern portion provided in a peripheral region thereof, and a sealing member that covers the second semiconductor chip on the first semiconductor chip and exposes an upper surface of the second semiconductor chip.

The measurement via pattern portion may include corner measurement pattern portions respectively provided at four corner portions of the second semiconductor chip and side measurement pattern portions respectively provided at four side portions of the second semiconductor chip. First and third dummy via structures of the corner measurement pattern portion may extend in a thickness direction from a first surface of the substrate of the second semiconductor chip to a second surface such that end portions thereof are exposed from the second surface of the substrate of the second semiconductor chip. Second and fourth dummy via structures of the side measurement pattern portions may extend in the thickness direction from the first surface of the substrate to a desired and/or alternatively predetermined depth such that end portions thereof are not exposed from the second surface of the substrate.

When viewed in plan view, portions of the first and third dummy via structures may be exposed from the second surface of the substrate and may be detected by an optical camera such as a vision camera. In contrast, portions of the second and fourth dummy via structures may be buried from the second surface of the substrate and thus may not be detected by an optical camera such as a vision camera.

According to an example embodiment, a method of manufacturing a semiconductor package may include stacking a semiconductor chip on a lower structure, the lower structure being wafer or an interposer, the semiconductor chip including a substrate having a first surface facing the lower structure and a second surface opposing the first surface, a front insulating layer on the first surface of the substrate, and a measurement via pattern portion in a peripheral region of the substrate; and forming a sealing member on the semiconductor chip and on the lower structure, the sealing member exposing the second surface of the substrate of the semiconductor chip. The measurement via pattern portion may include first dummy via structures and second dummy via structures. The first dummy via structures may extend in a thickness direction from the first surface of the substrate to the second surface such that end portions of the first dummy via structures may be exposed from the second surface of the substrate. The second dummy via structures may extend in the thickness direction from the first surface of the substrate to a depth in the substrate such that end portions of the second dummy via structures may not be exposed from the second surface of the substrate.

In some embodiments, the lower structure may be the wafer.

In some embodiments, the lower structure may be the interposer.

In some embodiments, a length difference between the first dummy via structures and the second dummy via structures may be within a range of 5 μm to 50 μm.

In some embodiments, the second surface of the substrate and a surface of the sealing member may be coplanar.

In manufacturing the semiconductor package, alignment accuracy of the second semiconductor chip may be inspected by capturing the measurement via pattern portion. In addition, the measurement via pattern portion exposed from the upper surface of the second semiconductor chip exposed by the sealing member may be captured to measure a thickness of the second semiconductor chip 200 and a thickness variation (Total Thickness Variation, TTV) of the entire surface of the second semiconductor chip.

In addition, since the first, second, third, and fourth dummy via structures of the measurement via pattern portion having a relatively high thermal expansion coefficient are formed in the peripheral region of the second semiconductor chip, warpage of the second semiconductor chip at a high temperature may be prevented or reduced.

### BRIEF DESCRIPTION OF THE DRAWINGS

Example embodiments will be more clearly understood from the following detailed description taken in conjunction with the accompanying drawings. FIGS. 1 to 23 represent non-limiting, example embodiments as described herein.

FIG. 1 is a cross-sectional view illustrating a semiconductor package in accordance with example embodiments.

FIG. 2 is an enlarged cross-sectional view illustrating portion ‘A’ in FIG. 1.

FIG. 3 is a plan view illustrating the semiconductor package of FIG. 1.

FIG. 4 is a cross-sectional view illustrating the semiconductor package of FIG. 1 mounted on a package substrate.

FIGS. 5 to 21 are views illustrating a method of manufacturing a semiconductor package in accordance with example embodiments.

FIG. 22 is a cross-sectional view illustrating a semiconductor package in accordance with example embodiments.

FIG. 23 is an enlarged cross-sectional view illustrating portion ‘H’ in FIG. 22.

### DETAILED DESCRIPTION OF EXAMPLE EMBODIMENTS

Hereinafter, example embodiments will be explained in detail with reference to the accompanying drawings.

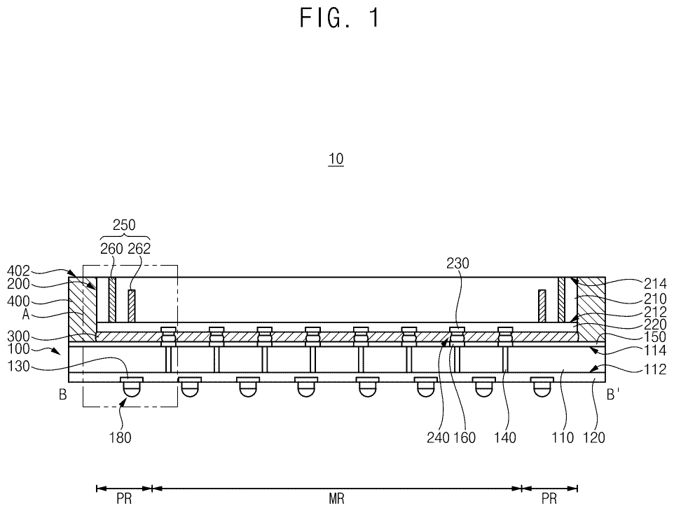

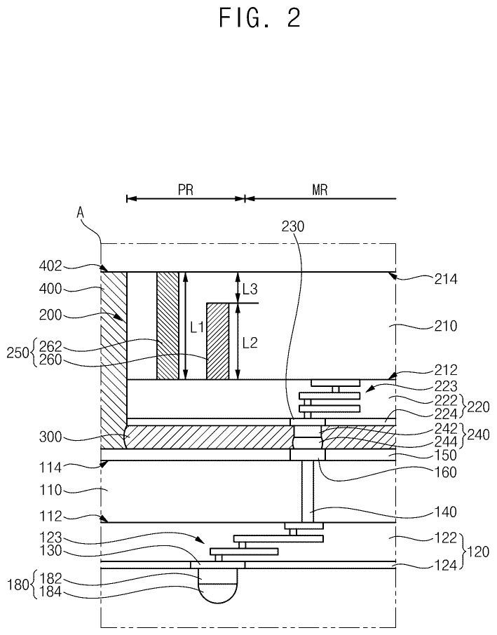

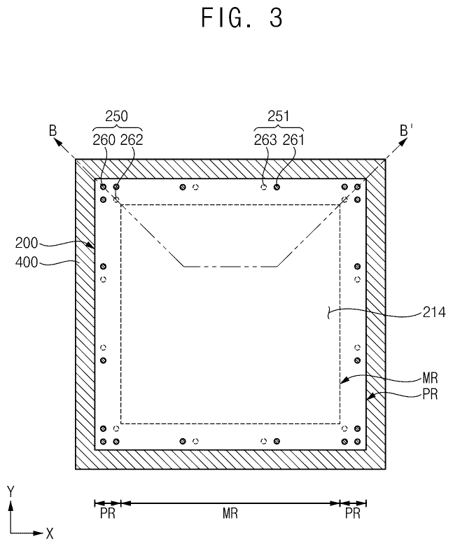

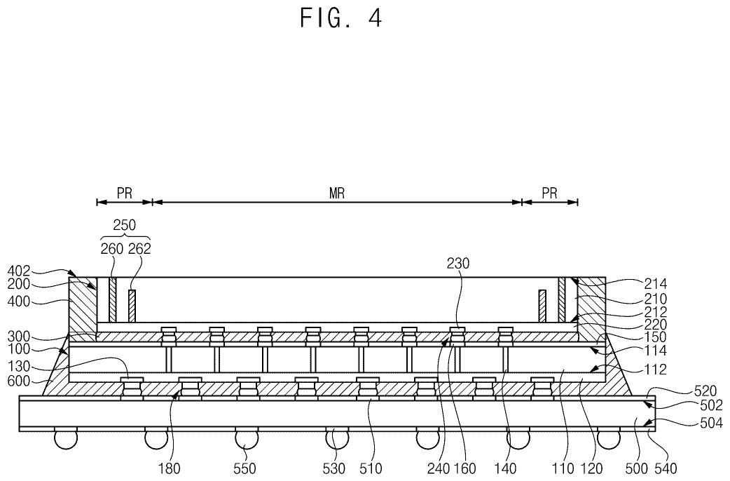

FIG. 1 is a cross-sectional view illustrating a semiconductor package in accordance with example embodiments. FIG. 2 is an enlarged cross-sectional view illustrating portion ‘A’ in FIG. 1. FIG. 3 is a plan view illustrating the semiconductor package of FIG. 1. FIG. 4 is a cross-sectional view illustrating the semiconductor package of FIG. 1 mounted on a package substrate. FIG. 1 includes a cross-sectional portion taken along the line B-B′ in FIG. 3.

Referring to FIGS. 1 to 4, a semiconductor package 10 may include a first semiconductor chip 100, a second semiconductor chip 200 that is stacked on the first semiconductor chip 100 and has measurement via pattern portions 250 and 251, and a sealing member 400 that covers the second semiconductor chip 200 on the first semiconductor chip 100 and exposes an upper surface 214 of the second semiconductor chip 200. In addition, the semiconductor package 10 may further include an adhesive layer 300 interposed between the first and second semiconductor chips 100 and 200, a package substrate 500 on which the stacked first and second semiconductor chips 100 and 200 are mounted, and external connection members 550 that are provided on a lower surface of the package substrate 500.

In addition, the semiconductor package 10 may be a multi-chip package (MCP) including different types of semiconductor chips. The semiconductor package 10 may be a system in package (SIP) including a plurality of semiconductor chips stacked or arranged in one package to perform all or most of the functions of an electronic system. The semiconductor package 10 may be a package with a 3D chip structure.

The semiconductor package 10 may include the first semiconductor chip 100 as a logic chip and the second semiconductor chips 200 as a memory chip, sequentially stacked. The first semiconductor chip 100 may be a logic chip including a logic circuit. The logic chip may be a controller that controls memory devices of the second semiconductor chip. The first semiconductor chip may be an ASIC serving as a host such as CPU, GPU, or SOC, or serving as a processor chip such as an application processor (AP). The second semiconductor chip may include DRAM, SRAM, etc.

In this embodiment, the semiconductor package as a multi-chip package is illustrated as including two stacked first and second semiconductor chips 100 and 200. However, it is not limited thereto, and for example, the semiconductor package may include 4, 8, 12, or 16 stacked semiconductor chips.

In example embodiments, the first semiconductor chip 100 may be a lower semiconductor chip and may include a first substrate 110, a first front insulating layer 120, a plurality of first bonding pads 130, a plurality of through electrodes 140, a first backside insulating layer 150, and a plurality of second bonding pads 160. In addition, the first semiconductor chip 100 may further include first conductive bumps 180 as first conductive connecting members respectively provided on the first bonding pads 130. The first semiconductor chip 100 may be mounted on the package substrate 500 via the first conductive bumps 180.

The first substrate 110 may have a first surface 112 and a second surface 114 opposite to each other. The first surface may be an active surface, and the second surface may be an inactive surface. Circuit patterns and cells may be formed on the first surface 112 of the first substrate 110. For example, the first substrate 110 may be a single crystal silicon substrate. The circuit patterns may include transistors, capacitors, diodes, etc. The circuit patterns may constitute circuit elements. Accordingly, the first semiconductor chip 100 may be a semiconductor device in which a plurality of the circuit elements is formed.

The first front insulating layer 120 may be provided on the first surface 112 of the first substrate 110, that is, the active surface. The first front insulating layer 120 may include a plurality of insulating layers and upper wirings 123 within the insulating layers. In addition, the first bonding pads 130 may be provided in an outermost insulating layer of the first front insulating layer 120.

The through electrode as a through silicon via (TSV) 140 may be provided to vertically penetrate the first substrate 110 from the first surface 112 to the second surface 114 of the first substrate 110. A first end portion of the through electrode 140 may contact the upper wiring of the first wiring layer. However, it is not limited thereto, and for example, the through electrode 140 may extend through the first front insulating layer and may directly contact the first bonding pad 130.

The first backside insulating layer 150 may be provided on the second surface 114, e.g., the back surface, of the first substrate 110. The second bonding pads 160 may be provided in the first backside insulating layer 150. The second bonding pad 160 may be arranged on the exposed surface of the through electrode 140. Accordingly, the first and second bonding pads 130 and 160 may be electrically connected to each other by the through electrode 140.

The first and second bonding pads 130 and 160 may be arranged in respective arrays on the upper and lower surfaces of the first semiconductor chip, and the through electrodes 140 may be provided in the first substrate 110 to be arranged in an array form. For example, the via arrangement of the through electrodes 140 may correspond to the pad arrangement of the second bonding pads 160.

In example embodiments, the second semiconductor chip 200 may include a second substrate 210, a second front insulating layer 220 and a plurality of third bonding pads 230. In addition, the second semiconductor chip 200 may further include second conductive bumps 240 as second conductive connection members respectively provided on the third bonding pads 230. The second semiconductor chip 200 may be mounted on the first semiconductor chip 100 via the second conductive bumps 240.

The second substrate 210 may have a first surface 212 and a second surface 214 opposite to each other. The first surface may be an active surface, and the second surface may be an inactive surface. Circuit elements may be formed on the first surface 212 of the second substrate 210. The circuit element may include a plurality of memory devices. Examples of the memory device may include a volatile semiconductor memory device and a non-volatile semiconductor memory device. An insulation interlayer covering the circuit elements may be formed on the first surface 212 of the second substrate 210.

The second front insulating layer 220 may include a metal wiring layer 222 and a protective layer 224 sequentially stacked on the first surface 212 of the second substrate 210. The metal wiring layer 222 may include a plurality of insulating layers and upper wirings 223 in the insulating layers. The third bonding pads 230 may be provided in an outermost insulating layer of the second front insulating layer 220.

The protective layer 224 may be formed on the metal wiring layer 222 and may expose at least a portion of the third bonding pad 230. The protective layer 224 may include a plurality of stacked insulating layers. For example, the protective layer 224 may include silicon oxide, silicon nitride, or silicon carbonitride. The protective layer 224 may have a single-layer or multi-layer structure. The protective layer 224 may be provided with the third bonding pad 230. The third bonding pad 230 may be exposed through an outer surface of the protective layer 224.

The sizes and thicknesses of the first and second semiconductor chips, the number, size, arrangement, etc. of the insulating layers of the front insulating layer and the upper wirings are provided as examples, and it will be understood that the present inventive concept is not limited thereto. For example, the first semiconductor chip may have a thickness in a range of 50 μm to 120 μm, and the second semiconductor chip may have a thickness in a range of 40 μm to 700 μm.

The second conductive bumps 240 may be respectively provided on the third bonding pads 230. The second conductive bumps 240 may include a pillar bump 242 and a solder bump 244 formed on the pillar bump 242. For example, the pillar bump may have a single-layer structure. The pillar bump may include a plating pattern layer including copper. The solder bump may include solder. The solder bump may include, for example, tin (Sn), tin/silver (Sn/Ag), tin/copper (Sn/Cu), tin/indium (Sn/In), tin/silver/copper (Sn/Ag/Cu), or the like.

In example embodiments, the second semiconductor chip 200 may be mounted on the first semiconductor chip 100 via the second conductive bumps 240. The second semiconductor chip 200 may be arranged on the first semiconductor chip 100 such that the first surface 212 of the second substrate 210 faces the first semiconductor chip 100. The second semiconductor chip 200 may be arranged on the first semiconductor chip 100 such that the second surface 214 of the second substrate 210 faces upward. The second conductive bump 240 of the second semiconductor chip 200 may be bonded to the second bonding pad 160 of the first semiconductor chip 100. A planar area of the second semiconductor chip 200 may be smaller than a planar area of the first semiconductor chip 100. When viewed in plan view, the second semiconductor chip 200 may be placed within the first semiconductor chip 100.

As illustrated in FIG. 2, the second conductive bump 240 of the second semiconductor chip 200 may be bonded to the second bonding pad 160 of the first semiconductor chip 100 by a flip chip bonding process. Accordingly, the third bonding pad 230 of the second semiconductor chip 200 may be electrically connected to the second bonding pad 160 of the first semiconductor chip 100 by the second conductive bump 240.

In example embodiments, the adhesive layer 300 may be provided to fill a space between the second conductive bumps 240 and the adhesive layer 300 may be between the first semiconductor chip 100 and the second semiconductor chip 200. For example, the adhesive layer may include a non-conductive film (NCF).

For example, the second semiconductor chip 200 and the first semiconductor chip 100 may be attached to each other by a thermal compression process using the non-conductive film. In the thermal compression process, the non-conductive film may be liquefied and have fluidity, and may flow between the second conductive bumps 240 between the second semiconductor chip 200 and the first semiconductor chip 100, and then may be cured to fill the space between the second conductive bumps 240. A portion of the cured adhesive layer 300 may protrude from a side surface of the second semiconductor chip 200.

In example embodiments, the sealing member 400 may cover the second semiconductor chip 200 on the first semiconductor chip 100. The sealing member 400 may cover the side surface of the second semiconductor chip 200. An upper surface of the second semiconductor chip 200, that is, the second surface 214 of the second substrate 210 may be exposed by the sealing member 400. For example, the sealing member 400 may include a thermosetting resin or the like. The second surface 214 of the second substrate 210 and an upper surface of the sealing member 400 may be positioned on the same plane.

In example embodiments, the second substrate 210 of the second semiconductor chip 200 may include a central region MR and a peripheral region PR surrounding the central region MR. A width of the peripheral region PR, e.g., a distance between an outer side of the second substrate 210 and the central region MR may be within a range of 200 μm to 500 μm. The measurement via pattern portions 250 and 251 may be provided within the peripheral region PR of the second substrate 210.

As illustrated in FIGS. 2 and 3, the measurement via pattern portions 250 and 251 may include corner measurement pattern portions 250 respective provided at four corner portions of the second substrate 210 and side measurement pattern portions 251 respectively provided at four side portions. The corner measurement pattern portion 250 may include at least one first dummy via structure 260 and at least one second dummy via structure 262. The first and second dummy via structures 260 and 262 may be arranged adjacent to each other at each of the corner portions. The side measurement pattern portion 251 may include at least one third dummy via structure 261 and at least one fourth dummy via structure 263. The third and fourth dummy via structures 261, 263 may be arranged adjacent to each other on each of the side portion.

The first and third dummy via structures 260 and 261 may extend in a thickness direction from the first surface 212 of the second substrate 210 to the second surface 214. End portions of the first and third dummy via structures 260 and 261 may be exposed from the second surface 214 of the second substrate 210. The first and third dummy via structures 260 and 261 may have a first length L1. The first length L1 may be equal to a thickness of the second substrate 210.

The second and fourth dummy via structures 262 and 263 may extend in the thickness direction from the first surface 212 of the second substrate 210 by a second length L2. End portions of the second and fourth dummy via structures 262, 263 may be buried in the second substrate 210 without being exposed from the second surface 214 of the second substrate 210. The second length L2 may be smaller than the first length L1. A difference L3 between the first length L1 and the second length L2 may be within a range of 5 μm to 50 μm. The end portions of the buried second and fourth dummy via structures 262 and 263 may be at a depth within a range of 5 μm to 50 μm from the second surface 214 of the second substrate 210.

Diameters of the first, second, third and fourth dummy via structures may be within a range of 50 μm to 200 μm. A spacing distance between the first dummy via structure 260 and the second dummy via structure 262 may be at least 150 μm. A spacing distance between the third dummy via structure 261 and the fourth dummy via structure 264 may be at least 150 μm.

As illustrated in FIG. 3, when viewed in plan view, portions of the first and third dummy via structures 260 and 261 may be exposed from the second surface 214 of the second substrate 210 and may be detected by an optical camera such as a vision camera. In contrast, portions of the second and fourth dummy via structures 262 and 263 may be buried from the second surface 214 of the second substrate 210 and may not be detected by an optical camera such as a vision camera.

In example embodiments, the package substrate 500 may be a substrate having an upper surface 502 and a lower surface 504 opposite to each other. For example, the package substrate 500 may be a printed circuit board (PCB). The printed circuit board may be a multilayer circuit board having vias and various circuits therein.

The first semiconductor chip 100 may be mounted on the package substrate 500 via the first conductive bumps 180. The first surface 112 of the first substrate 110 of the first semiconductor chip 100 may face the package substrate 500. The first conductive bump 180 of the first semiconductor chip 100 may be bonded to a substrate pad 510 on an upper surface 502 of the package substrate 500. A planar area of the first semiconductor chip 100 may be smaller than a planar area of the package substrate 500. When viewed in plan view, the first semiconductor chip 100 may be disposed within the package substrate 500. The first conductive bump 180 may include a pillar bump 182 and a solder bump 184 formed on the pillar bump 182.

In example embodiments, an underfill member 600 may be interposed between the first semiconductor chip 100 and the package substrate 500. For example, the underfill member may include an epoxy material to reinforce a gap between the first semiconductor chip 100 and the package substrate 500.

External connection pads 530 may be provided on the lower surface 504 of the package substrate 500, and the external connection members 550 may be respectively disposed on the external connection pads 530. For example, the external connection member 550 may be a solder ball. The semiconductor package 10 may be mounted on a module substrate (not illustrated) via the solder balls to form a memory module.

As mentioned above, the semiconductor package 10 may include the first semiconductor chip 100, the second semiconductor chip 200 that is stacked on the first semiconductor chip 100 via the second conductive bumps 240 and has the measurement via pattern portions 250 and 251 provided in the peripheral region PR thereof, and the sealing member 400 that covers the second semiconductor chip 200 on the first semiconductor chip 100 and exposes the second surface 214 of the second semiconductor chip 200.

The measurement via pattern portion may include the corner measurement pattern portions 250 respectively provided at four corner portions of the second substrate 210 and the side measurement pattern portions 251 respectively provided at four side portions of the second substrate 210. The corner measurement pattern portion 250 may include the at least one first dummy via structure 260 and the at least one second dummy via structure 262. The side measurement pattern portion 251 may include the at least one third dummy via structure 261 and the at least one fourth dummy via structure 263.

The first and third dummy via structures 260 and 261 may extend in the thickness direction from the first surface 212 of the second substrate 210 to the second surface 214 such that end portions thereof are exposed from the second surface 214 of the second substrate 210. The second and fourth dummy via structures 262, 263 may extend in the thickness direction from the first surface 212 of the second substrate 210 to the desired and/or alternatively predetermined depth L2 such that end portions thereof are not exposed from the second surface 214 of the second substrate 210.

When viewed in plan view, portions of the first and third dummy via structures 260 and 261 may be exposed from the second surface 214 of the second substrate 210 and may be detected by an optical camera such as a vision camera. In contrast, portions of the second and fourth dummy via structures 262, 263 may be buried from the second surface 214 of the second substrate 210 and thus may not be detected by an optical camera such as a vision camera.

After the second semiconductor chip 200 is mounted on the first semiconductor chip 100, alignment accuracy of the second semiconductor chip 200 may be inspected by detecting the measurement via pattern portions 250 and 251. In addition, a grinding process may be performed to partially remove the upper surface of the sealing member 400 that covers the second semiconductor chip 200 on the first semiconductor chip 100. At this time, the measurement via pattern portions 250 and 251 exposed from the second surface 214 of the second semiconductor chip 200 exposed by the sealing member 400 may be captured to measure a thickness of the second semiconductor chip 200 and a thickness variation (Total Thickness Variation, TTV) of the entire surface of the second semiconductor chip 200.

In addition, at a high temperature in a solder reflow process, the second semiconductor chip 200 may experience a smile-shaped warpage due to a difference in thermal expansion coefficients between the metal wirings in the second substrate 210 and the second front insulating layer 220. Since the first, second, third, and fourth dummy via structures of the measurement via pattern portions 250 and 251 having a relatively high thermal expansion coefficient are formed in the peripheral region PR of the second semiconductor chip 200, warpage of the second semiconductor chip 200 at a high temperature may be prevented or reduced. Accordingly, the bonding characteristics between the second conductive bump and the third bonding pad at the chip corner may be improved.

Hereinafter, a method of manufacturing the semiconductor package of FIG. 1 will be described.

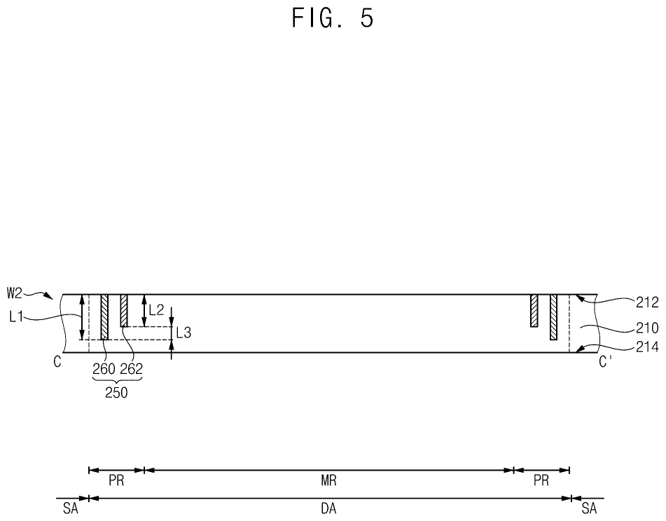

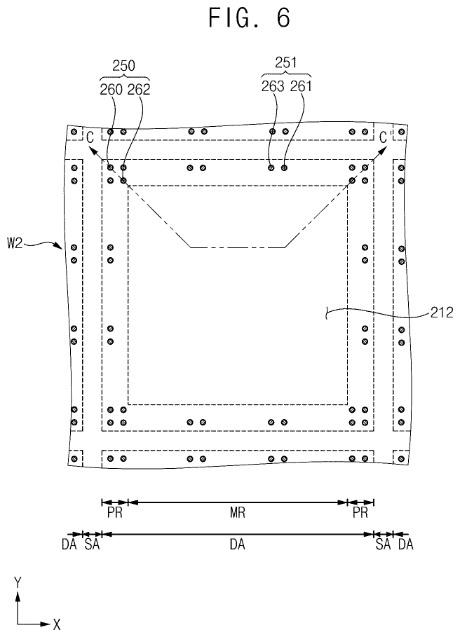

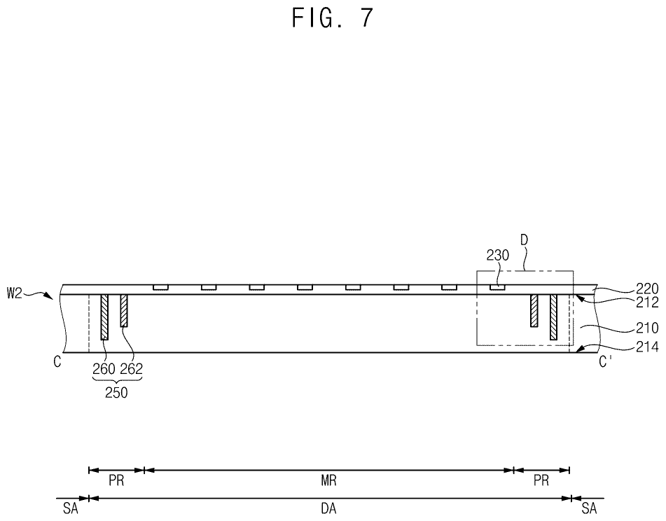

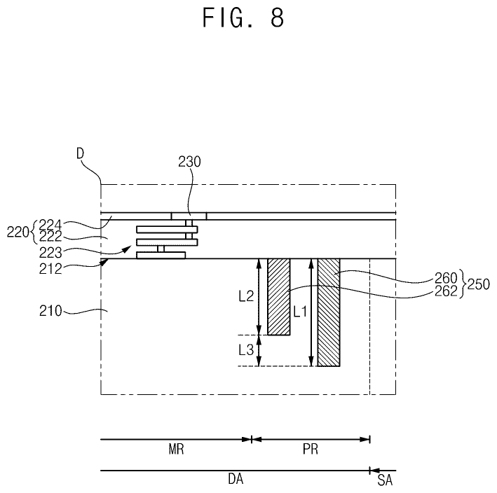

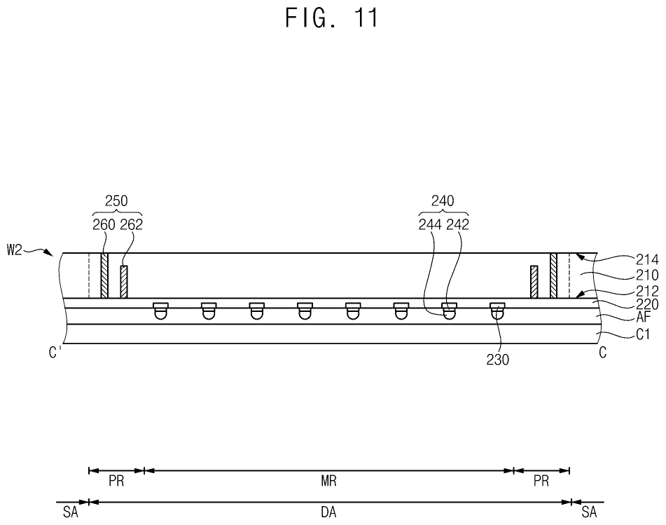

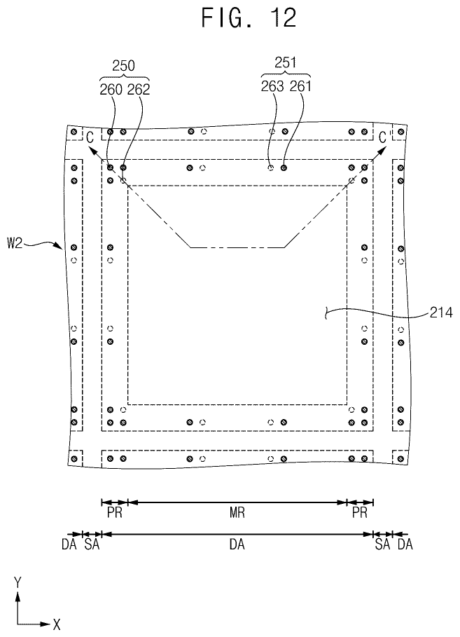

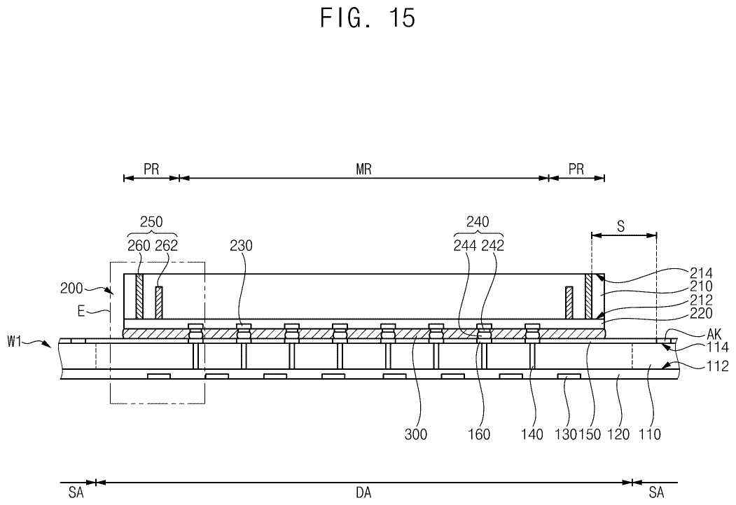

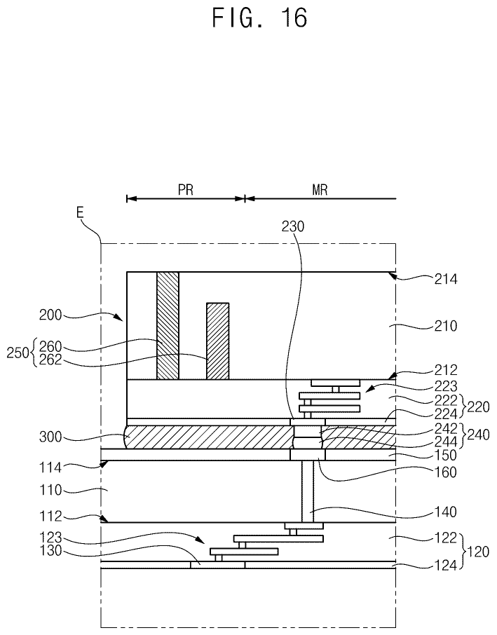

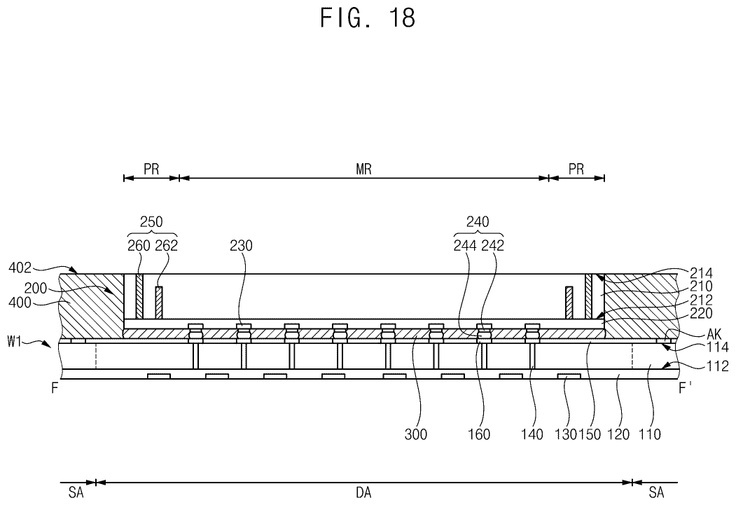

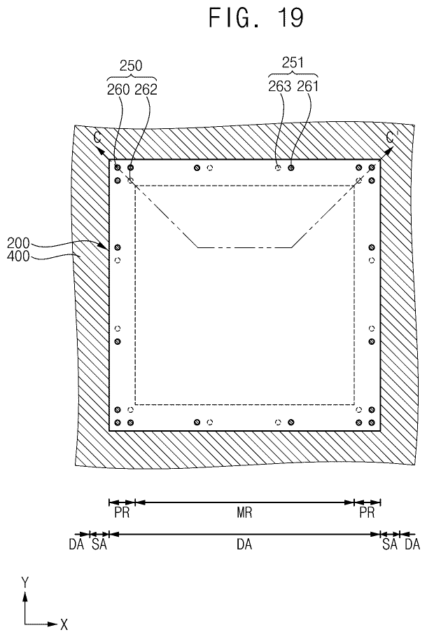

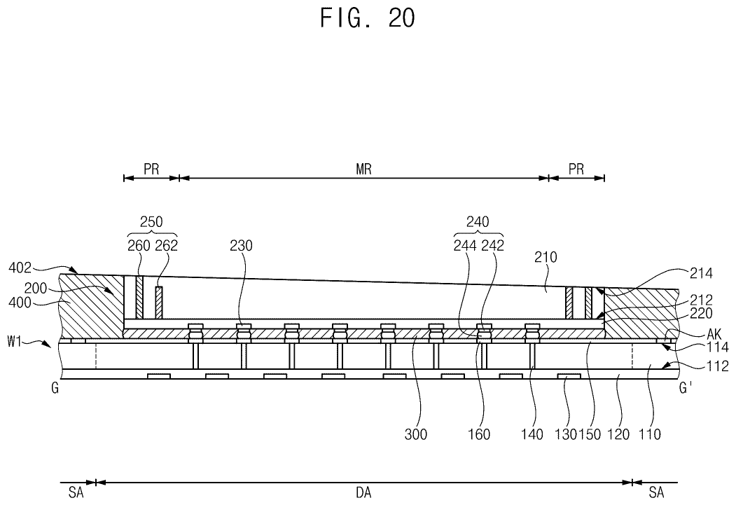

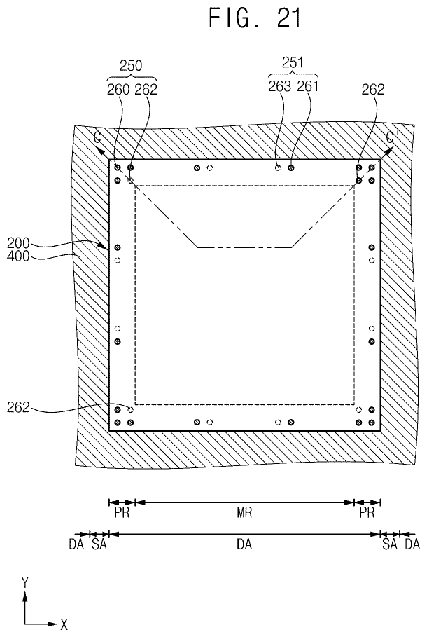

FIGS. 5 to 21 are views illustrating a method of manufacturing a semiconductor package in accordance with example embodiments. FIGS. 5, 7, 9, 10, 11, 13, 14, 15, 17, 18, and 20 are cross-sectional views illustrating a method of manufacturing a semiconductor package in accordance with example embodiments. FIG. 6 is a plan view of FIG. 5. FIG. 8 is an enlarged cross-sectional view illustrating portion ‘D’ in FIG. 7. FIG. 12 is a plan view of FIG. 11. FIG. 16 is an enlarged cross-sectional view illustrating portion ‘E’ in FIG. 15. FIG. 19 is a plan view of FIG. 18. FIG. 21 is a plan view of FIG. 20. FIGS. 5, 7, 9, 10, 11, and 13 are cross-sectional views taken along the line C-C′ in FIG. 6. FIG. 18 is a cross-sectional view taken along the line F-F′ in FIG. 19. FIG. 20 is a cross-sectional view taken along the line G-G′ in FIG. 21.

Referring to FIGS. 5 to 13, a second semiconductor chip 200 may be formed as an upper semiconductor chip including measurement via pattern portions 250 and 251.

As illustrated in FIGS. 5 and 6, dummy via structures 260, 261, 262, and 263 as the measurement via pattern portion may be formed in the second wafer W2.

In example embodiments, the second wafer W2 may include a second substrate 210 having a first surface 212 and a second surface 214 opposite to the first surface 212. The second substrate 210 may include a die region DA and a scribe lane region SA surrounding the die region DA. The second substrate 210 may be cut along the scribe lane region SA that divides the plurality of die regions DA of the second wafer W2 by a following sawing process to be individualized into a plurality of second semiconductor chips. Each die region DA may include a central region MR and a peripheral region PR surrounding the central region MR. A width of the peripheral region PR, e.g., a distance between an outer side of the die region DA and the central region MR may be within a range of 200 μm to 500 μm.

For example, the second substrate 210 may include silicon, germanium, silicon-germanium, or III-V compounds, e.g., GaP, GaAs, GaSb, etc. In some embodiments, the second substrate 210 may be a silicon-on-insulator (SOI) substrate, or a germanium-on-insulator (GOI) substrate.

In example embodiments, a photoresist pattern may be formed on the first surface 212 of the second substrate 210 to expose via structure regions, and the second substrate 210 may be partially etched using the photoresist pattern as an etching mask to form a plurality of trenches. The plurality of trenches may be formed in the peripheral region PR. The plurality of trenches may have first trenches and second trenches. The first trenches may be formed to have a first depth from the first surface 212 of the second substrate 210, and the second trenches may have a second depth less than the first depth from the first surface 212 of the second substrate 210. The plurality of trenches may have a circular or rectangular cross-sectional shape.

Then, an insulating layer may be formed on the first surface 212 of the second substrate 210 and inner walls of the trenches, and a conductive layer may be formed to sufficiently fill the trenches. The insulating layer may be formed to include, for example, an oxide such as silicon oxide or a nitride such as silicon nitride. The conductive layer may be formed using, for example, a metal such as copper (Cu), aluminum (Al), tungsten (W), or doped polysilicon. When the conductive layer is formed using copper or aluminum, a seed layer may be formed on the insulating layer, and then the conductive layer may be formed by an electroplating process. In addition, a barrier layer may be sequentially formed on the insulating layer, and the barrier layer may be formed to include a metal nitride such as titanium nitride, tantalum nitride, tungsten nitride, copper nitride, aluminum nitride, etc.

Then, the conductive layer and the insulating layer may be planarized until the first surface 212 of the second substrate 210 is exposed, to form via structures (e.g., dummy via structures 260, 261, 262, and 263) that fill the trenches.

Accordingly, the measurement via pattern portions 250 and 251 may be formed in the second substrate 210. The measurement via pattern portion may include corner measurement pattern portions 250 respectively formed at four corner portions and side measurement pattern portions 251 respectively formed at four side portions. The corner measurement pattern portion 250 may include at least one first dummy via structure 260 and at least one second dummy via structure 262. The first and second dummy via structures 260 and 262 may be arranged adjacent to each other at each of the corner portions. The side measurement pattern portion 251 may include at least one third dummy via structure 261 and at least one fourth dummy via structure 263. The third and fourth dummy via structures 261, 263 may be arranged adjacent to each other on each of the side portion.

The first and third dummy via structures 260 and 261 may have a first length L1 from the first surface 212 of the second substrate 210. The second and fourth dummy via structures 262, 263 may have a second length L2 from the first surface 212 of the second substrate 210. The second length L2 may be smaller than the first length L1. A difference L3 between the first length L1 and the second length L2 may be within a range of 5 μm to 50 μm. Diameters of the first, second, third and fourth dummy via structures may be within a range of 50 μm to 200 μm. A spacing distance between the first dummy via structure 260 and the second dummy via structure 262 may be at least 150 μm. A spacing distance between the third dummy via structure 261 and the fourth dummy via structure 264 may be at least 150 μm.

As illustrated in FIGS. 7 and 8, a second front insulating layer 220 having third bonding pads 230 therein may be formed on the first surface 212 of the second substrate 210.

In example embodiments, a Fab process called a front end of line (FEOL) process for manufacturing semiconductor devices may be performed on the die region DA to form circuit elements on the first surface 212 of the second substrate 210.

The circuit elements may be formed in the die region DA on the first surface 212 of the second substrate 210. The circuit element may include a plurality of memory devices. Examples of the memory device may be a volatile semiconductor memory device and a non-volatile semiconductor memory device. Examples of the volatile semiconductor memory device may be DRAM, SRAM, etc. Examples of the non-volatile semiconductor memory device may be EPROM, EEPROM, Flash EEPROM, etc.

The circuit elements may include, for example, transistors, capacitors, wiring structures, etc. A surface of the second substrate on which the FEOL process is performed may be referred to as a front surface of the second substrate, and a surface opposite to the front surface may be referred to as a backside surface. An insulation interlayer covering the circuit elements may be formed on the first surface 212 of the second substrate 210.

Then, a wiring process called a back-end-of-line (BEOL) process may be performed to form the second front insulating layer 220 on the first surface 212 of the second substrate 210. The second front insulating layer 220 may include a metal wiring layer 222 and a protective layer 224 sequentially stacked on the second substrate 210.

The metal wiring layer 222 may include a plurality of insulating layers and upper wirings 223 in the insulating layers. Additionally, the third bonding pads 230 may be provided in an outermost insulating layer of the second front insulating layer 220. The protective layer 224 may be formed on the metal wiring layer 222 and may expose the third bonding pads 230.

For example, the insulating layers may be formed of an oxide such as silicon oxide, carbon-doped oxide, or fluorine-doped oxide. The protective layer may include a passivation layer including a nitride such as silicon nitride (SiN). The upper wirings may include a metal material such as aluminum (Al), copper (Cu), etc. The third bonding pads 230 may be electrically connected to the circuit elements through the upper wirings 223 and contact plugs in the insulation interlayer. For example, the third bonding pads 230 may include copper (Cu), aluminum (Al), tungsten, nickel (Ni), molybdenum (Mo), gold (Au), silver (Ag), chromium (Cr), tin (Sn), titanium (Ti), etc.

The number, size, arrangement, etc. of the insulating layers, the upper wirings, the bonding pads of the front insulating layer are provided as examples, and it will be understood that it is not limited thereto.

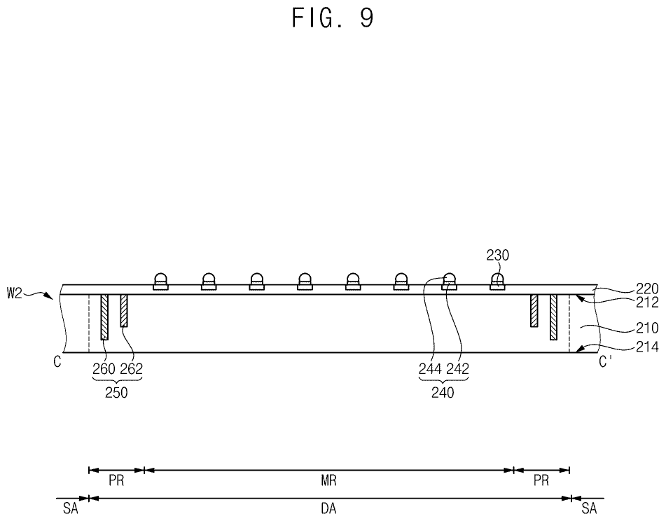

As illustrated in FIG. 9, second conductive bumps 240 may be formed on the third bonding pads 230 on the second front insulating layer 220, respectively.

In example embodiments, a seed layer may be formed on the third bonding pads 230 on the protective layer 224, a photoresist pattern having openings that expose bump regions of the seed layer may be formed, and the openings of the photoresist pattern may be filled with a conductive material to form the second conductive bumps 240. The second conductive bump 240 may include a pillar bump 242 and a solder bump 244 formed on the pillar bump 242. For example, the pillar bump may have a single-layered structure. The pillar bump may include a plating pattern layer including copper. The solder bump may include solder. The solder bumps may include, for example, tin (Sn), tin/silver (Sn/Ag), tin/copper (Sn/Cu), tin/indium (Sn/In), tin/silver/copper (Sn/Ag/Cu), etc.

Alternatively, the pillar bump may have a multilayer structure. In this case, the pillar bump may include first, second and third plating pattern layers that are sequentially stacked. For example, the first and third plating pattern layers may include copper (Cu), and the second plating pattern layer may include nickel (Ni).

Then, the photoresist pattern may be removed from the second wafer W2 and portions of the seed layer exposed by the second conductive bumps may be removed to form a seed film pattern.

In some example embodiments, the second conductive bumps may be formed by a screen printing method, a deposition method, or the like. The second conductive bumps may include solder bumps.

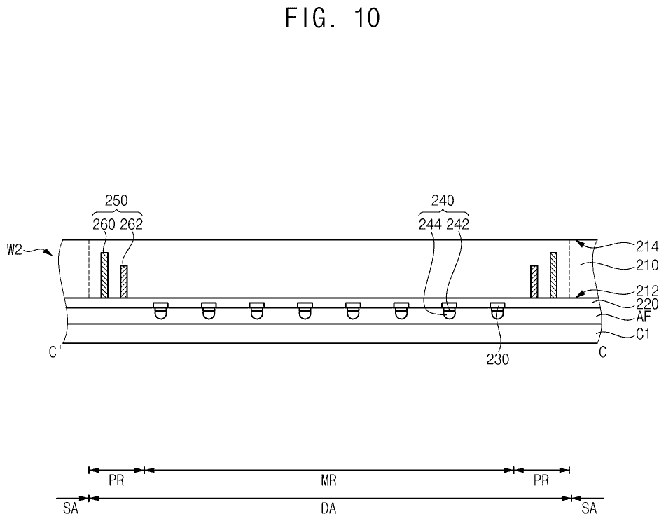

As illustrated in FIGS. 10 to 12, the second surface 214 of the second substrate 210 may be partially removed to expose portions of the first and third dummy via structures 260 and 261.

First, the structure of FIG. 9 may be turned over, and the second wafer W2 may be attached onto a first carrier substrate C1 using the first adhesive film AF1, and then the second surface 214 of the second substrate 210 may be removed until portions of the first and third dummy via structures 260 and 261 are exposed.

The second surface 214 of the second substrate 210 may be partially removed by a grinding process such as a back lap process. The second surface 214 of the second substrate 210 may be removed until the portions of the first and third dummy via structures 260 and 261 are exposed. At this time, the second and fourth dummy via structures 262, 263 may be buried without being exposed from the second side 214 of the second substrate 210. End portions of the buried second and fourth dummy via structures 262, 263 may be at a depth within a range of 5 μm to 50 μm from the second side 214 of the second substrate 210.

As illustrated in FIG. 12, when viewed in plan view, the portions of the first and third dummy via structures 260 and 261 may be exposed from the second surface 214 of the second substrate 210 and may be detected by an optical camera such as a vision camera. In contrast, portions of the second and fourth dummy via structures 262, 263 may be buried from the second surface 214 of the second substrate 210 and may not be detected by the optical camera such as the vision camera.

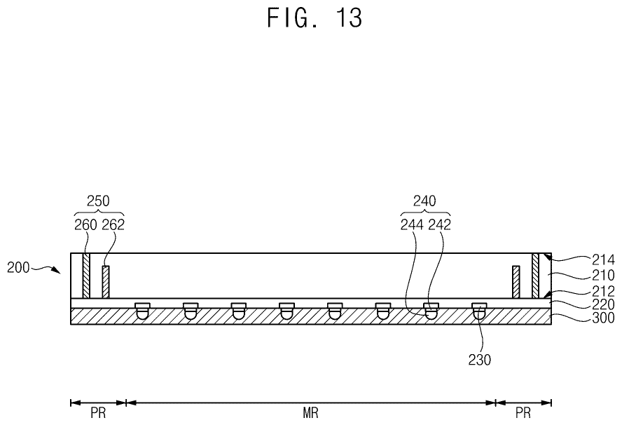

As illustrated in FIG. 13, the second wafer W2 may be cut along the scribe lane region SA to form an individualized second semiconductor chip 200. The second wafer W2 may be cut by a sawing process. An adhesive layer 300 may be attached to the second semiconductor chip 200 in order to adhere the second semiconductor chip 200 to a first wafer, which will be described later. The adhesive layer 300 may be formed on the second wiring layer 220, which also may be referred to as the second front insulating layer 220, to cover the second conductive bumps 240. For example, the adhesive layer 300 may include a thermosetting resin. The adhesive layer 300 may include a non-conductive film (NCF). In some embodiments, the adhesive layer 300 may be formed on the second wiring layer 220 of the second wafer W2 before performing the sawing process.

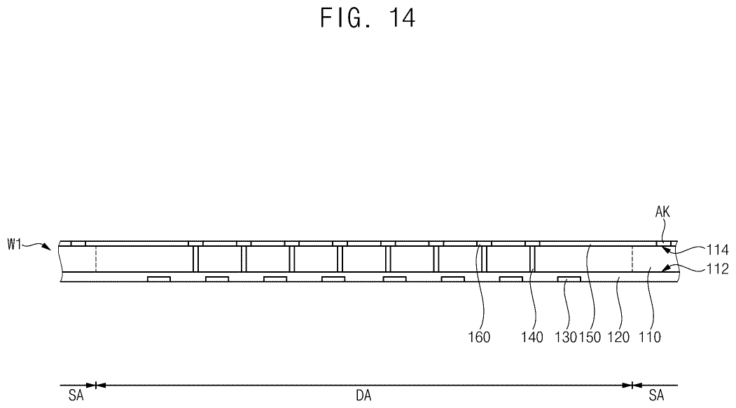

Referring to FIGS. 14 to 16, the second semiconductor chip 200 may be stacked on a first wafer W1. The second semiconductor chip 200 may be mounted on the first wafer W1 via the second conductive bumps 240.

As illustrated in FIG. 14, the first wafer W1 including a plurality of first semiconductor chips (dies) formed therein may be provided.

In example embodiments, the first wafer W1 may include a first substrate 110 having a first surface 112 and a second surface 114 opposite to the first surface 112. The first substrate 110 may include a die region DA and a scribe lane region SA surrounding the die region DA. The first substrate 110 may be cut along the scribe lane region SA that divides the plurality of die regions DA of the first wafer W1 by a following sawing process to be individualized into a plurality of first semiconductor chips.

Circuit elements may be formed in the die region DA on the first surface 112 of the first substrate 110. The first semiconductor chip may be a logic chip including a logic circuit. The logic chip may be a controller that controls the memory devices of the second semiconductor chip. The first semiconductor chip may be an ASIC serving as a host such as CPU, GPU, or SOC, or serving as a processor chip such as an application processor (AP).

The circuit elements may include, for example, transistors, capacitors, wiring structures, etc. The circuit elements may be formed on the first surface 112 of the first substrate 110 by performing a Fab process called a front end of line (FEOL) process for manufacturing semiconductor devices. A surface of the first substrate on which the FEOL process is performed may be referred to as a front side surface of the first substrate, and a surface opposite to the front side surface may be referred to as a backside surface. An insulation interlayer covering the circuit elements may be formed on the first surface 112 of the first substrate 110.

The first wafer W may include a first front insulating layer 120 provided on the first surface 112 of the first substrate 110, first bonding pads 130 provided on an outer surface of the first front insulating layer 120, a first backside insulating layer 150, second bonding pads 160 provided on an outer surface of the first backside insulating layer 150, and through electrodes 140 penetrating the first substrate 110 and electrically connecting the first and second bonding pads 130 and 160 to each other.

Alignment key patterns AK may be provided on the first surface 112 of the first wafer W1. For example, an oxide layer may be formed on the first surface 112 of the first substrate 110, and a patterning process and a plating process may be performed on the oxide layer to form the alignment key patterns AK. The alignment key patterns AK may include a metal material such as aluminum, copper, etc. The alignment key patterns AK may be formed within the scribe lane region SA or in a peripheral region of the die region DA. A process of attaching the upper semiconductor chip 200 onto the lower semiconductor chip of the first wafer W1 may be performed using the alignment key patterns AK.

As illustrated in FIGS. 15 and 16, the second semiconductor chip 200 may be stacked on the first wafer W1 using a substrate support system WSS. The second semiconductor chips 200 may be disposed on the first wafer W1 to correspond to the die regions DA, respectively. The second semiconductor chip 200 may be attached on the first wafer W1 using the adhesive layer 300. The second semiconductor chip 200 may be arranged such that the first surface 212 of the second substrate 210 faces the first wafer W1.

The second semiconductor chip 200 may be bonded onto the first wafer W1 by a flip chip bonding method. The second conductive bumps 240 may be bonded to the second bonding pads 160 of the first wafer W1 respectively by a solder reflow process using a convection reflow apparatus, a mass reflow apparatus, a laser-assisted bonding apparatus, or the like. In the bonding process, the non-conductive film may be liquefied and has fluidity, and may flow between the second semiconductor chip 200 and the first wafer W1. The nonconductive film having fluidity may flow between the second conductive bumps 240 and then be cured to fill a space between the second conductive bumps 240. A portion of the cured adhesive layer 300 may protrude from a side surface of the second semiconductor chip 200.

Then, the alignment key pattern AK and the measurement via pattern portions 250 and 251 exposed from the second surface 214 of the second semiconductor chip 200 may be photographed to check alignment accuracy. For example, the alignment key pattern AK and the first and third dummy via structures 260 and 261 may be photographed with an optical camera, and a distance S between the alignment key pattern AK and the first and third dummy via structures 260 and 261 may be measured to inspect or check the alignment accuracy.

In related arts, the alignment accuracy of the second semiconductor chip 200 on the first wafer W1 was measured using an infrared camera. The infrared camera may transmit infrared light through the second substrate 210 and detect the alignment key pattern formed on the second front insulating layer 220, to check the alignment accuracy of the second semiconductor chip 200. However, there was a problem that operating costs of the infrared camera was high. In contrast, in example embodiments, since the alignment accuracy of the second semiconductor chip 200 may be checked using an optical camera such as a vision camera, the alignment accuracy of the second semiconductor chip 200 may be checked at a lower cost.

In addition, under a high temperature of the solder reflow process, the second semiconductor chip 200 may experience a smile-shaped warpage due to a difference in thermal expansion coefficient between the metal wirings in the second substrate 210 and the second front insulating layer 220. Since the first, second, third and fourth dummy via structures of the measurement via pattern portions 250 and 251 having a relatively high thermal expansion coefficient are formed in the peripheral region PR of the second semiconductor chip 200, the warpage of the second semiconductor chip 200 at high temperatures may be prevented or reduced. Accordingly, the bonding characteristics between the second conductive bump and the third bonding pad at the chip corner portion may be improved.

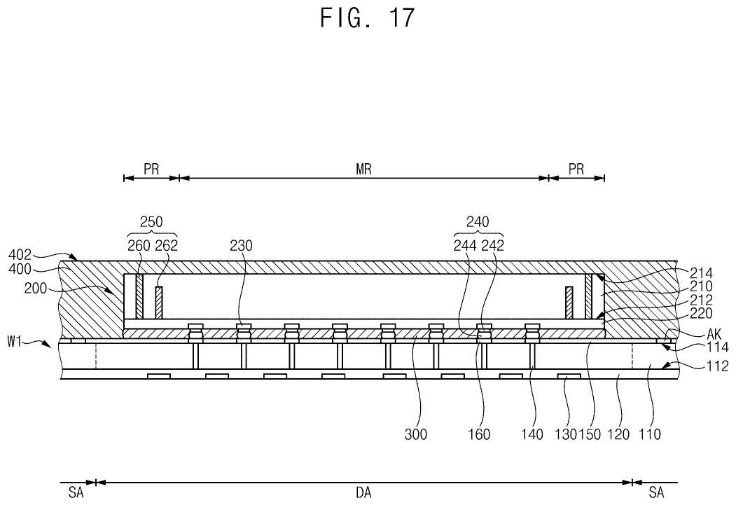

Referring to FIGS. 17 to 19, a sealing member 400 may be formed on the first wafer W1 to cover the second semiconductor chip 200.

As illustrated in FIG. 17, the sealing member 400 may be formed on the first wafer W1 to cover upper surfaces of the second semiconductor chips 200 and fill spaces between the second semiconductor chips 200. The sealing member 400 may be formed by a dispensing process or a spin coating process. For example, the sealing member 400 may include a thermosetting resin or the like.

As illustrated in FIGS. 18 and 19, an upper surface 402 of the sealing member 400 may be partially removed to expose the upper surface of the second semiconductor chip 200, e.g., the second surface 214.

The upper surface 402 of the sealing member 400 may be partially removed by a grinding process. The upper surface 402 of the sealing member 400 may be removed until the second surface 214 of the second semiconductor chip 200 is partially exposed. At this time, the second surface 214 of the second semiconductor chip 200 may be partially removed together. After the grinding process, the upper surface of the sealing member 400 may be positioned on the same plane as the second surface 214 of the second semiconductor chip 200.

Then, the measurement via pattern portions 250 and 251 exposed from the second surface 214 of the second semiconductor chip 200 exposed by the sealing member 400 may be photographed to measure a thickness of the second semiconductor chip 200 and a change in the thickness (Total Thickness Variation, TTV) of the entire surface of the second semiconductor chip 200. For example, the measurement via pattern portions 250 and 251 exposed from the second surface 214 of the second semiconductor chip 200 may be photographed with an optical camera to check or measure the thickness and the total thickness variation of the second semiconductor chip 200.

If the first and third dummy via structures 260 and 262 are measured and the second and fourth dummy via structures 261, 263 are not measured in a specific region, it may be determined that the second semiconductor chip 200 is formed to have a desired thickness. In addition, as illustrated in FIG. 19, when the first and third dummy via structures 260 and 262 are measured over the entire peripheral region PR and the second and fourth dummy via structures 261, 263 are not measured, it may be determined that the total thickness change is not large and the second semiconductor chip 200 on which the grinding process has been performed has a uniform thickness.

As illustrated in FIGS. 20 and 21, when the first and third dummy via structures 260 and 262 as well as the second and fourth dummy via structures 261, 263 are measured in a specific region, it may be determined that the second semiconductor chip 200 on which the grinding process has been performed has a uniform thickness. For example, when the thickness of the second semiconductor chip 200 in a specific corner portion is relatively small, it may be determined that a defect occurred in the specific process area when the grinding process was performed.

In related arts, when the grinding process was performed, the thickness between the carrier substrate in the substrate support system WSS and the second surface 214 of the second semiconductor chip 200 was measured to check or inspect the thickness and total thickness variation of the second semiconductor chip 200. However, there was a problem that the thickness measurement accuracy decreased as the thickness of the second semiconductor chip 200 increased due to the accumulation of thickness tolerances of the carrier substrate and the adhesive film. In contrast, in example embodiments, the thickness and total thickness variation of the second semiconductor chip 200 may be accurately checked or inspected by capturing an image of the measurement via pattern portions 250 and 251 using an optical camera such as a vision camera.

Then, first conductive bumps 180, see FIG. 1 may be formed on the first bonding pads 130 of the first wafer W1. For example, the first conductive bumps 180 may be formed on the first bonding pads 130 of the first wafer W1 by performing processes the same as or similar to the processes described with reference to FIG. 9.

Then, the first wafer W1 and the sealing member 400 may be cut along the scribe lane region SA to form an individualized first semiconductor chip 100. Thus, a semiconductor package 10 (also referred to as a stack package 10, see FIG. 1), in which the second semiconductor chip 200 is stacked on the first semiconductor chip 100, may be formed.

Then, the stack package may be mounted on a package substrate 500.

In example embodiments, the first semiconductor chip 100 may be mounted on the package substrate 500 via the first conductive bumps 180. The first surface 112 of the first substrate 110 of the first semiconductor chip 100 may face the package substrate 500. The first conductive bump 180 of the first semiconductor chip 100 may be bonded to a substrate pad 510 on an upper surface 502 of the package substrate 500.

Then, an underfill member 600 may be underfilled between the first semiconductor chip 100 and the package substrate 500. While moving a dispenser nozzle along a side of the first semiconductor chip 100, an underfill solution may be dispensed between the first semiconductor chip 100 and the package substrate 500, and the underfill solution may be cured to form the underfill member 600.

For example, the underfill member may include an epoxy material to reinforce a gap between the first semiconductor chip 100 and the package substrate 500.

Then, external connection members 550 (see FIG. 4 may be formed on external connection pads 530 on a lower surface 504 of the package substrate 500 to complete the semiconductor package of FIG. 4.

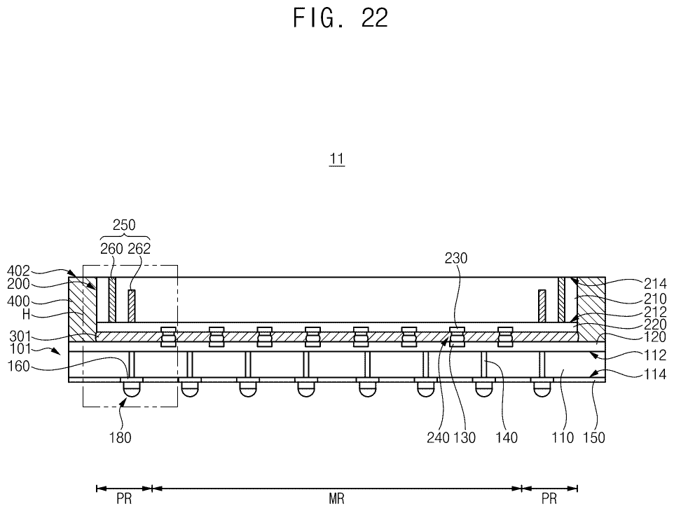

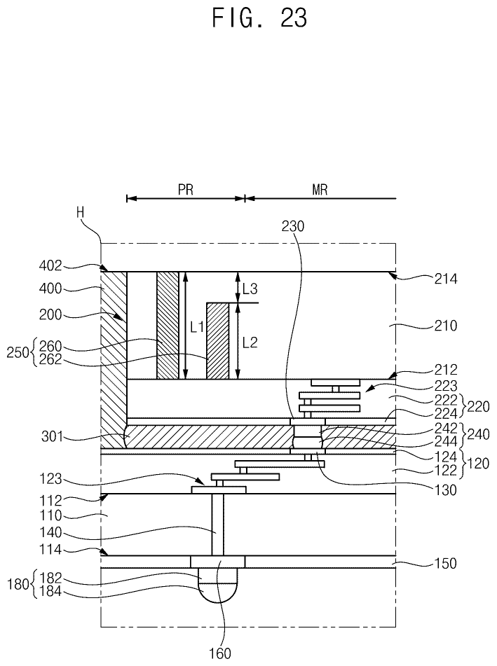

FIG. 22 is a cross-sectional view illustrating a semiconductor package in accordance with example embodiments. FIG. 23 is an enlarged cross-sectional view illustrating portion ‘H’ in FIG. 22. The semiconductor package is substantially the same as the semiconductor package described with reference to FIG. 1 except for a 2.5 D chip configuration. Thus, same reference numerals will be used to refer to the same or like elements and any further repetitive explanation concerning the above elements will be omitted.

Referring to FIGS. 22 and 23, a semiconductor package 11 may include an interposer 101, a semiconductor chip 200 stacked on the interposer 101 and having a measurement via pattern portion 250, and a sealing member 400 covering the semiconductor chip 200 on the interposer 101 and exposing an upper surface 214 of the semiconductor chip 200. In addition, the semiconductor package 11 may further include an underfill member 301 interposed between the interposer 101 and the semiconductor chip 200 and a package substrate on which the interposer 101 is mounted.

In example embodiments, the semiconductor package 11 may include a semiconductor memory device having a 2.5 D chip structure. The semiconductor package 11 may be a molded interposer package (MIP). The semiconductor package 11 including a memory device of the 2.5 D chip structure may include the interposer 101 for electrically connecting the semiconductor chip 200 to the package substrate 500. The semiconductor chip 200 as an upper semiconductor chip may be an ASIC serving as a host such as CPU, GPU, or SOC or serving as a processor chip such as an application processor AP.

In example embodiments, the interposer 101 may be a silicon interposer having a plurality of wirings 123 formed therein. Alternatively, the interposer 101 may be a redistribution wiring interposer. The semiconductor chip 200 may be electrically connected to the package substrate through the wirings formed inside the interposer 101.

The interposer 101 may include a first substrate 110, a wiring layer 120 having a plurality of wirings 123 on an upper surface of the first substrate 110, e.g., a first surface 112, a plurality of first bonding pads 130 provided on the wiring layer 120, and a plurality of second bonding pads 160 provided on a lower surface of the first substrate 110, e.g., a second surface 114. The wiring layer 120 may also be referred to as the first front insulating layer 120, such as in the description of FIG. 2.

As illustrated in FIGS. 22-23, the semiconductor chip 200 may be arranged on the interposer 101. The semiconductor chip 200 may be mounted on the interposer 101 by a flip chip bonding method. The semiconductor chip 200 may be mounted on the interposer 101 via second conductive bumps 240. The semiconductor chip 200 may be arranged such that a first surface 212 of a second substrate 210 faces the interposer 101. The second conductive bump 240 of the semiconductor chip 200 may be bonded to the first bonding pad 130 of the interposer 101. A planar area of the semiconductor chip 200 may be smaller than a planar area of the interposer 101. When viewed in plan view, the semiconductor chip 200 may be placed within the interposer 101.

The second conductive bump 240 of the semiconductor chip 200 may be bonded to the first bonding pad 130 of the interposer 101 by a flip chip bonding process. Accordingly, a third bonding pad 230 of the semiconductor chip 200 may be electrically connected to the first bonding pad 130 of the interposer 101 by the second conductive bump 240. The second conductive bump 240 may include a pillar bump 242 formed on the third bonding pad 230 of the semiconductor chip 200 and a solder bump 244 formed on the pillar bump 242.

In example embodiments, the underfill member 301 may be underfilled between the semiconductor chip 300 and the interposer 101 to fill spaces between the second conductive bumps 240.

The underfill member may include a material having relatively high fluidity to effectively fill the small space between the interposer and the semiconductor chip. For example, the underfill member may include an adhesive including an epoxy material.

In example embodiments, the sealing member 400 may cover the semiconductor chip 200 on the interposer 101. The sealing member 400 may cover a side surface of the semiconductor chip 200. The upper surface of the semiconductor chip 200, that is, the second surface 214 of the second substrate 210 may be exposed by the sealing member 400. For example, the sealing member 400 may include a thermosetting resin, etc. The second surface 214 of the second substrate 210 and an upper surface of the sealing member 400 may be positioned on the same plane.

The measurement via pattern portion may include a corner measurement pattern portion 250 provided at corner portions of the semiconductor chip 200. When viewed in plan view, a portion of the first dummy via structure 260 of the corner measurement pattern portion 250 may be exposed from the second surface 214 of the second substrate 210 and may be detected by an optical camera such as a vision camera. In contrast, a portion of the second dummy via structure 262 of the corner measurement pattern portion 250 may be buried from the second surface 214 of the second substrate 210 and may not be detected by an optical camera such as a vision camera.

The measurement via pattern portion may include a side measurement pattern portion provided at side portions of the semiconductor chip 200. A portion of a third dummy via structure of the side measurement pattern portion may be exposed from the second surface 214 of the second substrate 210 and may be detected by an optical camera such as a vision camera. In contrast, a portion of the fourth dummy via structure of the side measurement pattern portion may be buried from the second surface 214 of the second substrate 210 and may not be detected by an optical camera such as a vision camera.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A semiconductor package, comprising:
a lower semiconductor chip;
an upper semiconductor chip on the lower semiconductor chip, the upper semiconductor chip including a substrate having a first surface facing the lower semiconductor chip and a second surface opposing the first surface, a front insulating layer on the first surface of the substrate, and a measurement via pattern portion in a peripheral region of the substrate; and
a sealing member covering the upper semiconductor chip on the lower semiconductor chip and exposing the second surface of the substrate, wherein the measurement via pattern portion includes first dummy via structures and second dummy via structures,
the first dummy via structures extend in a thickness direction from the first surface of the substrate to the second surface such that end portions of the first dummy via structures are exposed from the second surface of the substrate, and
the second dummy via structures extend in the thickness direction from the first surface of the substrate to a depth in the substrate such that end portions of the second dummy via structures are not exposed from the second surface of the substrate.

2. The semiconductor package of claim 1, wherein a first group of dummy via structures among the first dummy via structures and the second dummy via structures are respectively arranged at corner portions of the substrate.

3. The semiconductor package of claim 1, wherein a second group of dummy via structures among the first dummy via structures and the second dummy via structures are respectively arranged at side portions of the substrate.

4. The semiconductor package of claim 1, wherein a length difference between the first dummy via structures and the second dummy via structures is within a range of 5 μm to 50 μm.

5. The semiconductor package of claim 1, wherein diameters of the first dummy via structures and the second dummy via structures are within a range of 50 μm to 200 μm.

6. The semiconductor package of claim 1, wherein
the peripheral region of the substrate has a first width from an outer side surface of the substrate, and
the first width is within a range of 200 μm to 500 μm.

7. The semiconductor package of claim 1, further comprising:
conductive bumps between the lower semiconductor chip and the upper semiconductor chip, the conductive bumps electrically connecting the lower semiconductor chip to the upper semiconductor chip; and
an adhesive layer filling a space between the conductive bumps and between the lower semiconductor chip and the upper semiconductor chip to attach the lower semiconductor chip and the upper semiconductor chip to each other.

8. The semiconductor package of claim 7, wherein the adhesive layer includes a non-conductive film (NCF).

9. The semiconductor package of claim 1, wherein the second surface of the substrate and an upper surface of the sealing member are coplanar.

10. The semiconductor package of claim 1, further comprising:
a package substrate,
wherein the lower semiconductor chip is mounted on the package substrate via conductive bumps.

11. A semiconductor package, comprising:
an interposer;
a semiconductor chip on the interposer, the semiconductor chip including a substrate having a first surface facing the interposer and a second surface opposing the first surface, a front insulating layer on the first surface of the substrate, and a measurement via pattern portion in a peripheral region of the substrate; and
a sealing member covering the semiconductor chip, wherein
the sealing member is on the interposer and exposes the second surface of the substrate,
wherein the measurement via pattern portion includes corner measurement pattern portions respectively provided at four corner portions of the substrate,
wherein each of the corner measurement pattern portions includes first dummy via structures and a second dummy via structures,
wherein the first dummy via structures extend in a thickness direction from the first surface of the substrate to the second surface such that end portions of the first dummy via structures are exposed from the second surface of the substrate, and
wherein the second dummy via structures extend in the thickness direction from the first surface of the substrate to a depth in the substrate such that end portions of the second dummy via structures are not exposed from the second surface of the substrate.

12. The semiconductor package of claim 11, wherein a length difference between the first dummy via structures and the second dummy via structures is within a range of 5 μm to 50 μm.

13. The semiconductor package of claim 11, wherein diameters of the first dummy via structures and second dummy via structures are within a range of 50 μm to 200 μm.

14. The semiconductor package of claim 11, wherein
the peripheral region of the substrate has a first width from an outer side surface of the substrate, and
the first width is within a range of 200 μm to 500 μm.

15. The semiconductor package in claim 11, further comprising:
side measurement pattern portions respectively provided at four side portions of the substrate, wherein
each of the side measurement pattern portions includes third dummy via structure and fourth dummy via structures,
the third dummy via structures extend in the thickness direction from the first surface of the substrate to the second surface of the substrate such that end portions of the third dummy via structures are exposed from the second surface of the substrate, and
the fourth dummy via structures extend in the thickness direction from the first surface of the substrate to a distance, the distance being less than a thickness of the substrate, such that end portions of the fourth dummy via structures are not exposed from the second surface of the substrate.

16. The semiconductor package of claim 11, further comprising:
conductive bumps between the interposer and the semiconductor chip, the conductive bumps electrically connecting the interposer to the semiconductor chip; and
an underfill member filling a space between the conductive bumps, wherein
the underfill member is between the interposer and the semiconductor chip.

17. The semiconductor package of claim 16, wherein the underfill member includes an epoxy material.

18. The semiconductor package of claim 11, wherein the second surface of the substrate and an upper surface of the sealing member are coplanar.

19. The semiconductor package of claim 11, further comprising:
a package substrate,
wherein the interposer is mounted on the package substrate via conductive bumps.

20. A semiconductor package, comprising:
a first semiconductor chip;
a second semiconductor chip on the first semiconductor chip, the second semiconductor chip having a central region and a peripheral region surrounding the central region, the second semiconductor chip including a measurement via pattern portion in the peripheral region; and
a sealing member covering the second semiconductor chip, the sealing member being on the first semiconductor chip and exposing an upper surface of the second semiconductor chip,
wherein the measurement via pattern portion includes corner measurement pattern portions respectively provided at four corner portions of the second semiconductor chip and side measurement pattern portions respectively provided at four side portions of the second semiconductor chip, and
wherein each of the corner measurement pattern portions and the side measurement pattern portions includes first dummy via structures and second dummy via structures,
wherein the first dummy via structures extend into at least a portion of the second semiconductor chip in a thickness direction such that end portions of the first dummy via structures are exposed from the upper surface of the second semiconductor chip, and
wherein the second dummy via structures extend partially through the second semiconductor chip in the thickness direction such that end portions of the second dummy via structures are not exposed from the upper surface of the second semiconductor chip.
